(19) United States
(12) Patent Application Publication
(10) Pub. No.: US 2010/0143081 A1
(43) Pub. Date: Jun. 10, 2010

(54) Semiconductor manufacturing apparatus and method

(76) Inventors: Hyeong-seob Oh, Suwon-si (KR); Yohan Ahn, Yongin-si (KR); Hyeong-Ki Kim, Hwaseong-si (KR); Ki-Doo Kim, Suwon-si (KR); Woo-Yong Lee, Anyang-si (KR); Min-Seon Lee, Yeongdo-gu (KR)

Correspondence Address: LEE & MORSE, P.C., 3141 FAIRVIEW PARK DRIVE, SUITE 500, FALLS CHURCH, VA, 22042, US

(21) Appl. No.: 12/591,592

(22) Filed: Nov. 24, 2009

(30) Foreign Application Priority Data
Dec. 2, 2008 (KR) 10-2008-0121013

(51) Int. Cl. H01L 21/677; H01L 21/673

(52) U.S. Cl. 414/217.1; 414/805

(57) ABSTRACT

A semiconductor manufacturing apparatus includes a load port supporting a FOUP holding a plurality of wafers, a process module performing a semiconductor manufacturing process on the plurality of wafers, an equipment front end module disposed between the load port and the process module, providing a clean area, and including an opener for opening and closing a door of the FOUP, a transfer module sequentially transferring the plurality of wafers between the FOUP and the process module, and a purge module spraying a purge gas toward the plurality of wafers in the FOUP when the door is open to connect the equipment front end module and the FOUP, so as to make gases released from the plurality of wafers be recovered into the equipment front end module.

### BACKGROUND

1. Field

Exemplary embodiments relate to a semiconductor manufacturing apparatus and a method. In particular, exemplary embodiments relate to a semiconductor manufacturing apparatus and a method for purging the inside of a carrier or a front opening unified pod holding wafers in the semiconductor manufacturing apparatus.

2. Description of the Related Art

In general, wafers may be oxidized and/or contaminated in air. For this reason, containers, e.g., front opening unified pods (FOUPs), are used for transferring wafers in semiconductor manufacturing. Moreover, in order to prevent wafers held in a container from being contaminated, the container may be filled with an inert gas, e.g., nitrogen or helium. Further, as various chemicals and gases may be required for semiconductor manufacturing apparatuses, such chemicals and gases may be purged.

### SUMMARY

Embodiments are directed to a semiconductor manufacturing apparatus and a method, which substantially overcome one or more of the problems due to the limitations and disadvantages of the related art.

It is therefore a feature of an embodiment to provide a semiconductor manufacturing apparatus with an increased efficiency of a purge gas flowing between wafers in an FOUP so as to improve or maximize production yield.

It is another feature of an embodiment to provide a semiconductor manufacturing apparatus with reduced wafer transfer time and wafer standby time so as to improve or maximize a production yield.

It is yet another feature of an embodiment to provide a method of manufacturing a semiconductor with a manufacturing apparatus having one or more of the above features.

At least one of the above and other features and advantages may be realized by providing a semiconductor manufacturing apparatus, including a load port supporting a FOUP holding a plurality of wafers, a process module performing a semiconductor manufacturing process on the plurality of wafers, an equipment front end module disposed between the load port and the process module, providing a clean area, and including an opener for opening and closing a door of the FOUP, a transfer module sequentially transferring the plurality of wafers between the FOUP and the process module, and a purge module spraying a purge gas toward the plurality of wafers in the FOUP when the door is opened to connect the equipment front end module and the FOUP, so as to make gases released from the plurality of wafers be recovered into the equipment front end module.

The purge module may include a sensor detecting whether the door is open, and at least one nozzle disposed vertically to processed surfaces of the plurality of wafers on at least one side of the FOUP and spraying the purge toward the plurality of wafers.

Each of the at least one nozzle may have a plurality of nozzle holes for spraying the purge gas toward the plurality wafers. The plurality of nozzle holes may be arranged vertically along an entire height of the FOUP. The plurality of nozzle holes may be aligned with respective wafers in the FOUP.

Each of the at least one nozzle may be provided on a lateral wall of the equipment front end module or a box opener/load-port-to-tool standard interface.

Each of the at least one nozzle may be configured to spray the purge gas at an angle of about 35 degrees to a box opener/load-port-to-tool standard interface.

The purge module may further include a gas tank supplying the purge gas to the at least one purge nozzle, at least one purge gas supply pipeline connecting the gas tank and the at least one purge nozzle, and at least one valve controlling the flow of the purge gas through the at least one purge gas supply pipeline in accordance with whether the door is open. The purge module may be inside the EFEM, the purge module including a plurality of nozzle holes arranged along a height of the FOUP. The transfer module may be configured to transfer the plurality of wafers directly between the FOUP and the process module.

At least one of the above and other features and advantages may also be realized by providing a semiconductor manufacturing method, including loading a FOUP holding a plurality of wafers on a load port, opening a door of the FOUP with an opener to connect the FOUP to an equipment front end module, beginning to spray a purge gas toward the plurality of wafers, taking out the plurality of wafers one-by-one and transferring them to a process module by a transfer module while spraying a purge gas into the FOUP, performing a semiconductor manufacturing process on the plurality of wafers, inserting the plurality of wafers into the FOUP, and continuing to spraying the purge gas to flow into the equipment front end module until the door of the FOUP is closed.

Transferring the plurality of wafers may include transferring the wafers one-by-one from the FOUP to the process module, while spraying the purge gas into the FOUP. Transferring the plurality of wafers may be performed directly between the FOUP and a respective process module. Inserting the plurality of wafers into the FOUP may include positioning processed wafers, after performing a semiconductor manufacturing process, in same respective initial positions in the FOUP. Transferring the plurality of wafers may be performed indirectly between the FOUP and a respective process module.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a schematic diagram of a semiconductor manufacturing apparatus according to an exemplary embodiment;

FIG. 2 illustrates a partial cross-sectional view of the semiconductor manufacturing apparatus shown in FIG. 1;

FIG. 3A illustrates a perspective view of a closed FOUP as seen from inside an EFEM shown in FIG. 1;

FIG. 3B illustrates a perspective view of an open FOUP as seen from inside an EFEM shown in FIG. 1;

FIG. 4 illustrates a plan view of a FOUP and nozzles of FIGS. 3A and 3B;

FIG. 5 illustrates an enlarged perspective view of a nozzle shown in FIGS. 3A and 3B;

FIG. 6 illustrates a schematic diagram of a purge module shown in FIGS. 3A and 3B;

FIG. 7 illustrates a flow chart of a semiconductor manufacturing method according to an exemplary embodiment; and

FIG. 8 illustrates graphs representing pollution levels according to the flow rates of the purge gas supplied to a FOUP.

### DETAILED DESCRIPTION

Korean Patent Application 10-2008-0121013, filed on Dec. 2, 2008, in the Korean Intellectual Property Office, and entitled: “Semiconductor Manufacturing Apparatus and Method,” is incorporated by reference herein in its entirety.

Exemplary embodiments will now be described more fully with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

Accordingly, while exemplary embodiments are capable of various modifications and alternative forms, embodiments thereof are shown by way of example in the drawings and will herein be described in detail. It should be understood, however, that there is no intent to limit exemplary embodiments to the particular forms disclosed, but on the contrary, exemplary embodiments are to cover all modifications, equivalents, and alternatives falling within the scope of exemplary embodiments. Like numbers refer to like elements throughout the description of the figures.

It will be understood that, although the terms first, second and third may be used herein to describe various elements, these elements should not be limited by these terms. These terms are only used to distinguish one element from another. For example, a first element could be termed a second element, and, similarly, a second element could be termed a first element, without departing from the scope of exemplary embodiments. As used herein, the term “and/or” includes any and all combinations of one or more of the associated listed items.

In the drawings figures, dimensions of elements and regions may be exaggerated for clarity. It will also be understood that when a layer or element is referred to as being “on” another layer or substrate, it can be directly on the other element or substrate, or intervening elements may also be present. In addition, it will also be understood that when an elements is referred to as being “between” two elements, it can be the only element between the two elements, or one or more intervening elements may also be present. Further, when an element is referred to as being “connected” or “coupled” to another element, it can be directly connected or coupled to the other element or intervening elements may be present. In contrast, when an element is referred to as being “directly connected,” “directly coupled,” or “directly between” elements, there are no intervening elements present. Other words used to describe the relationship between elements should be interpreted in a like fashion (e.g., “adjacent” versus “directly adjacent”, etc.).

Spatially relative terms, such as “beneath,” “below,” “lower,” “above,” “upper,” and the like may be used herein for ease of description to describe the relationship of one component and/or feature to another component and/or feature, or other component(s) and/or feature(s), as illustrated in the drawings. It will be understood that the spatially relative terms are intended to encompass different orientations of the device in use or operation in addition to the orientation depicted in the figures.

The terminology used herein is for the purpose of describing particular embodiments only and is not intended to be limiting of exemplary embodiments. As used herein, the singular forms “a”, “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which exemplary embodiments belongs. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

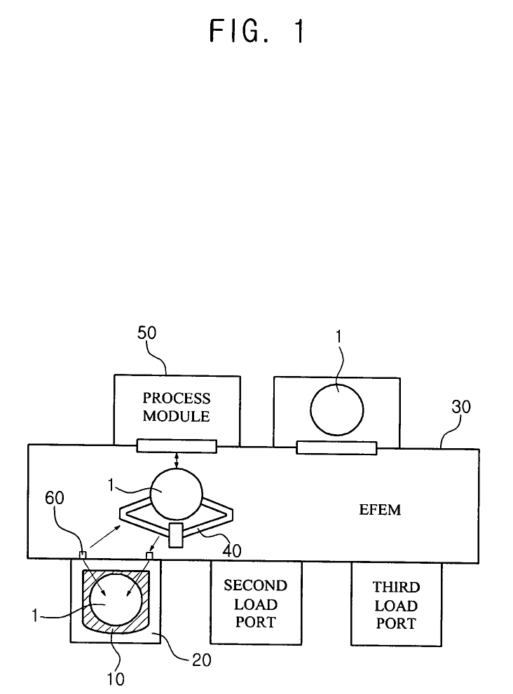

FIG. 1 illustrates a schematic diagram of a semiconductor manufacturing apparatus according to an exemplary embodiment. Referring to FIG. 1, a semiconductor manufacturing apparatus according an exemplary embodiment may include at least one load port 20 with a FOUP 10 thereon, at least one process module 50, and an equipment front end module (EFEM) 30 between the load port 20 and the process module 50. For example, as illustrated in FIG. 1, a single EFEM 30 may be connected between a plurality of load ports 20 and a plurality of process modules 50.

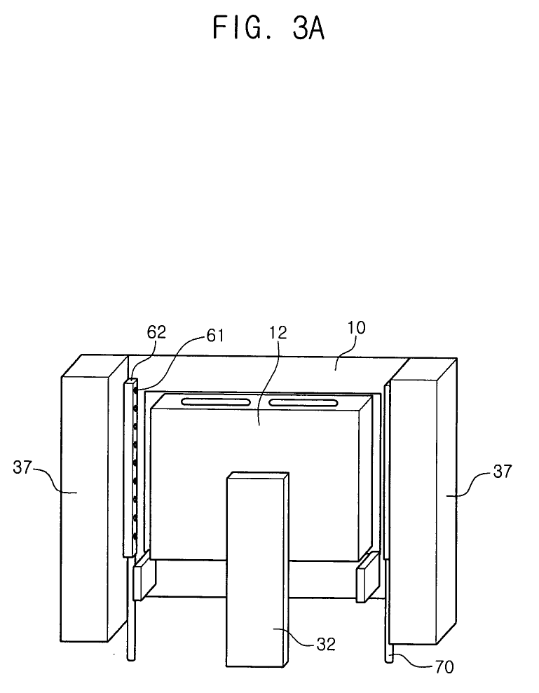

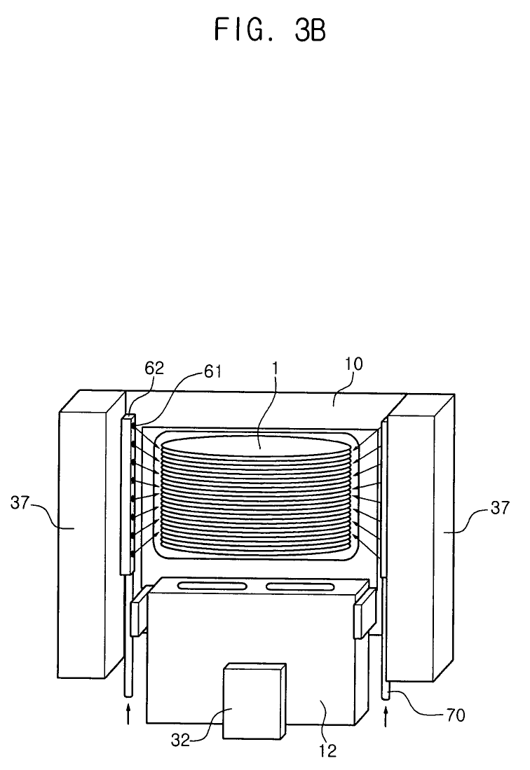

The EFEM 30 is an interface module that may supply wafers of the FOUPs 10 to the process modules 50, and may influence cleanliness and production yield of the semiconductor manufacturing apparatus. As illustrated in FIG. 1, the EFEM 30 may include a purge module 60 which sprays a purge gas on a plurality of wafers within the FOUP 10, and a transfer module 40, e.g., a robot arm, for transferring wafers 1 between the FOUPs 10 on the load ports 20 and may be integrated with the process modules 50. The purge gas sprayed from the purge module 60 into the FOUP 10 may be subsequently removed from the FOUP 10 to the EFEM 30. In other words, in the semiconductor manufacturing apparatus according to the exemplary embodiment, the purge gas may be sprayed from the EFEM 30 into the FOUP 10 of a load port 20, and then may be removed from the FOUP 10 back into the EFEM 30, resulting in increased purge efficiency. The purge module 60 of the EFEM 30 will be described in more detail below with reference to FIGS. 3A-6.

The load ports 20 of the semiconductor manufacturing apparatus may support the FOUPs 10 carried by, e.g., an overhead hoist transport system. The process modules 50 may perform various semiconductor manufacturing processes, and may include process chambers and load lock chambers.

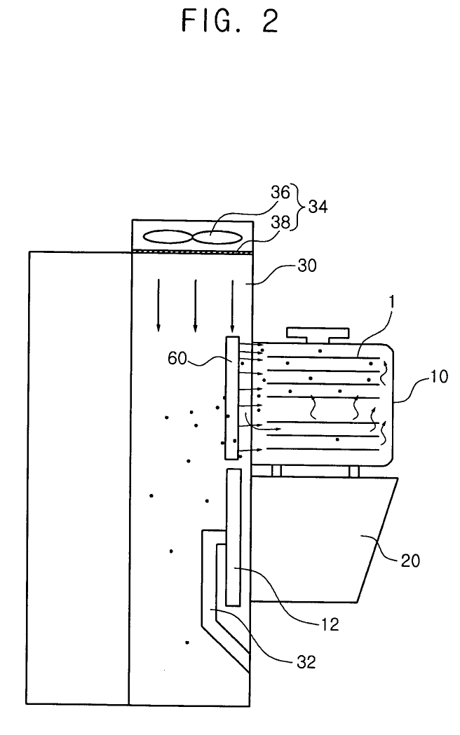

FIG. 2 illustrates a cross-sectional view of the FOUP 10 connected to the EFEM 30. Referring to FIG. 2, the FOUP 10 may be positioned on the load port 20, and may include a door 12 operated by an opener 32. For example, as illustrated in FIG. 2, when the opener 32 pulls the door 12 away from the FOUP 10, e.g., in a downward direction along a sidewall of the EFEM 30, an interior of the FOUP 10, i.e., the wafers 1 inside the FOUP 10, may be exposed to the EFEM 30. Therefore, when the door 12 is open, the purge module 60 of the EFEM 30 may spray the purge gas into the FOUP 10. Then, the purge gas may be recovered through the EFEM 30. As further illustrated in FIG. 2, the purge gas may be sprayed in a direction parallel with surfaces of the wafers 1, i.e., wafers in the FOUP 10 already processed or to be processed. Therefore, it may be possible to efficiently purge gases released from the wafers 1. Moreover, the purge gas flowing between the wafers 1 may be recovered to the EFEM 30 through an opening of the FOUP 10, so contaminants in the FOUP 10 may be recovered to the EFEM 30 with the recovered purge gas. Therefore, it may be possible to completely purge the FOUP 10.

As illustrated in FIG. 2, the EFEM 30 may further include an air cleaner 34. The air cleaner 34 may include a first air filter 38 and a fan 36. External air may be supplied to the air cleaner 34 through a plenum (not shown), and the fan 36 and the first air filter 38 may clean the external air and flow the clean air into the EFEM 30 at a predetermined pressure. Within the EFEM 30, air flows from the top to the bottom, as illustrated by the arrows in FIG. 2. Although not shown in FIG. 2, a second air filter may be formed at the lower end part of the EFEM 30 to clean air in the EFEM 30 and discharge the air to the outside through another plenum (not shown).

FIGS. 3A and 3B illustrate perspective views of closed and open FOUP 10, respectively, as seen from an interior of the EFEM 30. Referring to FIGS. 3A and 3B, the opener 32 may be configured on a lateral wall 37 of the EFEM 30 to open/close the door 12 covering the opening of the FOUP 10. As illustrated in FIGS. 3A and 3B, the purge module 60 may be on the lateral wall 37 of the EEFM 30, and may be adjacent to the opening of the FOUP 10. The purge module 60 may include nozzles 62 with nozzle holes 61, e.g., along the lateral wall 37 or a box opener/load-port-to-tool standard interface (hereinafter, referred to as BOLTS), for spraying the purging gas. For example, the nozzles 62 may have a rectangular shape, and may be on two opposite sides of the opening of the FOUP 10, as shown in FIGS. 3A and 3B. A plurality of nozzle holes 61 may be formed in each of the nozzles 62, so a plurality of nozzle holes 61 may extend along a side, e.g., along an entire side, of the opening of the FOUP 10. When the opener 32 of the EFEM 30 opens the door 12 of the FOUP 10, the EFEM 30 may be in fluid communication with the FOUP 10, so the purge gas may be sprayed from the nozzles 62 toward the FOUP 10.

The purge module 60 may spray the purge gas into the FOUP 10 when, e.g., only when, the FOUP 10 is completely open. That is, only if the door 12 of the FOUP 10 is completely open, the purge module 60 sprays the purge gas through the nozzle holes 61. The purge gas may be evenly sprayed between the wafers 1 of the FOUP 10. For example, if twenty-five (25) wafers are mounted in the FOUP 10, in order to spray a purge gas into gaps between the wafers 1, about 24 to 26 nozzle holes 61 may be formed in each nozzle 62, e.g., to be aligned with the wafers 1.

Although not shown, a separate module door for isolating the EFEM 30 from the external may be configured in the EFEM 30. In this case, when both the door 12 and the module door are open, the purge module 60 may perform a purging operation.

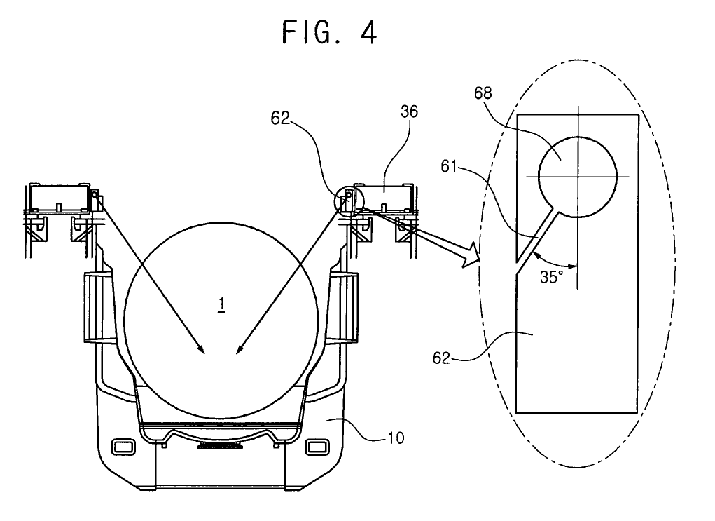

FIG. 4 illustrates a plan view of the relative structures of the FOUP 10 and the nozzles 62 of the purge module 60. As illustrated in FIG. 4, the purge module 60 may be peripheral with respect to the FOUP 10, so the nozzles 62 may not overlap the wafers 1 in the FOUP 10. In other words, as illustrated in FIG. 4, the nozzles 62 may be outside the FOUP 10, and a line connecting both ends of each nozzle hole 61, i.e., indicated by arrows in FIG. 4, may define an acute angle, e.g., about 35°, with respect to a respective adjacent sidewall of the FOUP 10, i.e., a corresponding BOLTS. The purge gas may be sprayed from the nozzles 62 toward the wafers 1 through the opening of the FOUP 10 along a direction indicated by the arrows in FIG. 4.

Each nozzle 62 may have an internal hole 68 and a predetermined number of nozzle holes 61. In each nozzle 62, the internal hole 68 may be formed in a longitudinal direction of the corresponding nozzle 62, and a predetermined number of nozzle holes 61 may be formed in a direction vertical to the longitudinal direction of the corresponding nozzle 62, e.g., the internal hole 68 may extend through an entire length of the nozzle 62 along a side of the FOUP 10. The nozzle holes 61 in each nozzle 62 may be aligned at predetermined intervals along the longitudinal direction of the corresponding nozzle 62, and may be in fluid communication with a corresponding internal hole of the nozzle. For example, as illustrated in FIG. 4, a first end of each nozzle hole 61 may be connected to the internal hole 68, and a second end of the nozzle hole 61 may be exposed to an exterior of the nozzle 62. Front surfaces of the nozzles 62, i.e., surfaces including the second ends of the nozzle holes 61, may be disposed to face each other, and rear surfaces of the nozzles 62, i.e., opposite respective front surfaces, may be attached to the lateral wall 37 of the EFEM 30.

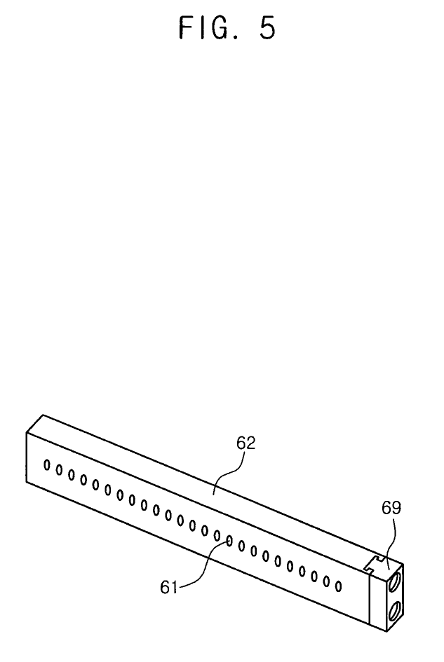

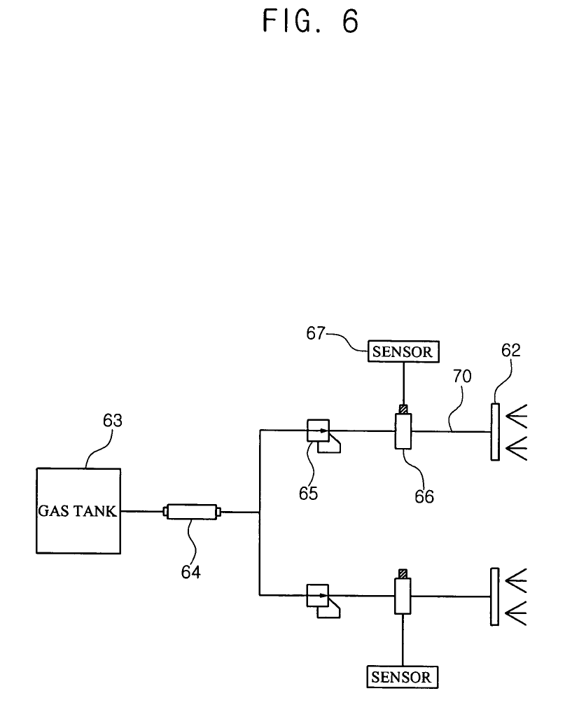

FIG. 5 illustrates a perspective view of an enlarged nozzle 62 according to example embodiments. The nozzle 62 may have a rectangular parallelepiped shape, and the nozzle holes 61 may be aligned along the longitudinal direction of the nozzle 62. Each internal hole 68 may be connected to a purge gas supply pipeline 70 directly (FIG. 6) or through a coupler 69 provided at one end side of a corresponding nozzle 62.

FIG. 6 illustrates a schematic diagram of the purge module 60. The purge module 60 may further include a gas tank 63, a flow meter 64, regulators 65 provided between the gas tank 63 and the nozzles 62, purge gas supply pipelines 70, and valves 66 for controlling the flow of the purge gas to the nozzles 62. The purge gas may be liquefied under high pressure, and then may be stored in the gas tank 63. For example, the purge gas may include nitrogen gas, so liquid nitrogen may be stored in the gas tank 63. The highly compressed liquid nitrogen may be supplied to the regulators 65, which evaporate the liquid nitrogen into nitrogen gas and supply the nitrogen gas to the nozzles 62. The nitrogen gas may be supplied at a predetermined pressure higher than normal pressure, and at a predetermined flow rate. For example, the predetermined pressure may be about 760 Torr, and the predetermined flow rate may be about 20 LPM to about 80 LPM.

As further illustrated in FIG. 6, the purge module 60 may further include a sensor 67 for sensing whether the FOUP door 12 is open. In order to sense the state of the FOUP door 12, the sensor 67 may sense the location of the FOUP door 12 or the opener 32, and may include a photo sensor. The valves 66 may be turned on/off on the basis of the result of the sensing of the sensor 67. Specifically, the valves 66 may be opened when the sensors 66 senses that the FOUP door 12 is open, such that the purge gas may be sprayed through the nozzle holes 61. The semiconductor manufacturing apparatus according to the exemplary embodiment may spray the purge gas whenever the FOUP 10 is open, e.g., completely open.

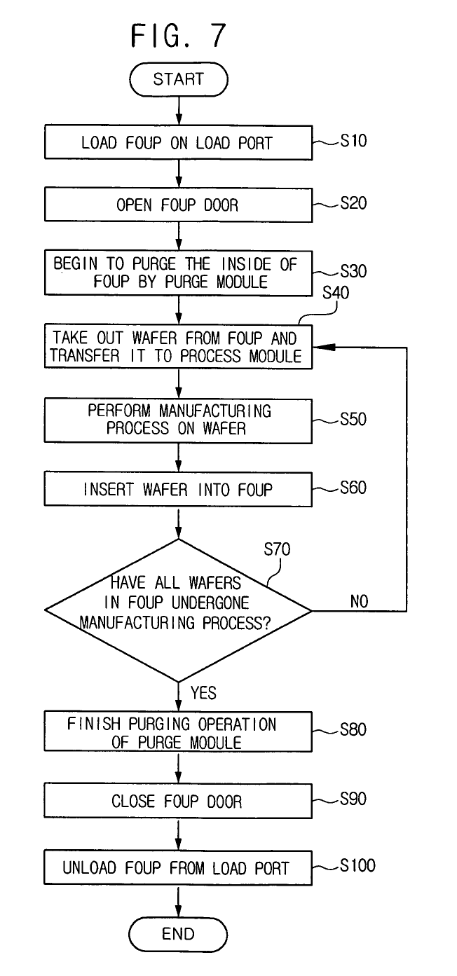

A semiconductor manufacturing method using a semiconductor manufacturing apparatus having the same configuration as described above will now be described with reference to FIG. 7. FIG. 7 illustrates a flow chart of a semiconductor manufacturing method according to an exemplary embodiment.

First, in operation S10, the FOUP 10 holding a plurality of wafers 1, e.g., a FOUP to be subjected to a semiconductor manufacturing process such as an etching process or a deposition process, may be loaded on the port load 20, such that the door 12 of the FOUP 10 may be adjacent to the module door of the EFEM 30. In other words, the FOUP 10 may be disposed such that a distance from the wafers 1 to a required process module 50 through the EFEM 30 is shortest.

Next, in operation S20, the module door of the EFEM 30 and the door 12 of the FOUP 10 may be opened. For example, the module door of the EFEM 30 may be opened first, and the door 12 may be opened by the opener 32 of the EFEM 30 to set the EFEM 30 and the FOUP 10 in fluid communication. As the door 12 is opened and the EFEM 30 and the FOUP 10 are in fluid communication, an internal pressure in the FOUP 10 may substantially equal that of the EFEM 30.

Subsequently, in operation S30, the purge module 60 may begin to purge the inside of the FOUP 10. Specifically, the purge module 60 may spray the purge gas from the supply tank 63 toward the wafers 1 of the FOUP 10 through the nozzles 62, as described previously with reference to FIGS. 4-6, in order to trigger an flow circulation within the FOUP 10. Then, the gas within the FOUP 10 may be forcibly discharged from the FOUP 10 to the EFEM 30. Therefore, since the purge module 60 injects the purge gas into the FOUP 10, followed by its removal from the FOUP 10, the purge module 60 may remove, i.e., during removal of the purge gas from the FOUP 10, any gases or contaminants remaining on the wafers 1 of the FOUP 10 to the EFEM 30. According to exemplary embodiments, since the nozzles 62 and nozzle holes 61 therein extend along entire length of the FOUP 10, the purge gas sprayed by the purge module 60 into the FOUP 10 may flow between the wafers 1, i.e., between every two adjacent wafers 1. As such, flow of the purge gas may contact surfaces of all the wafers 1, e.g., both top and bottom surfaces of each wafer 1, thereby increasing purging efficiency of the wafers 1 in the FOUP 10.

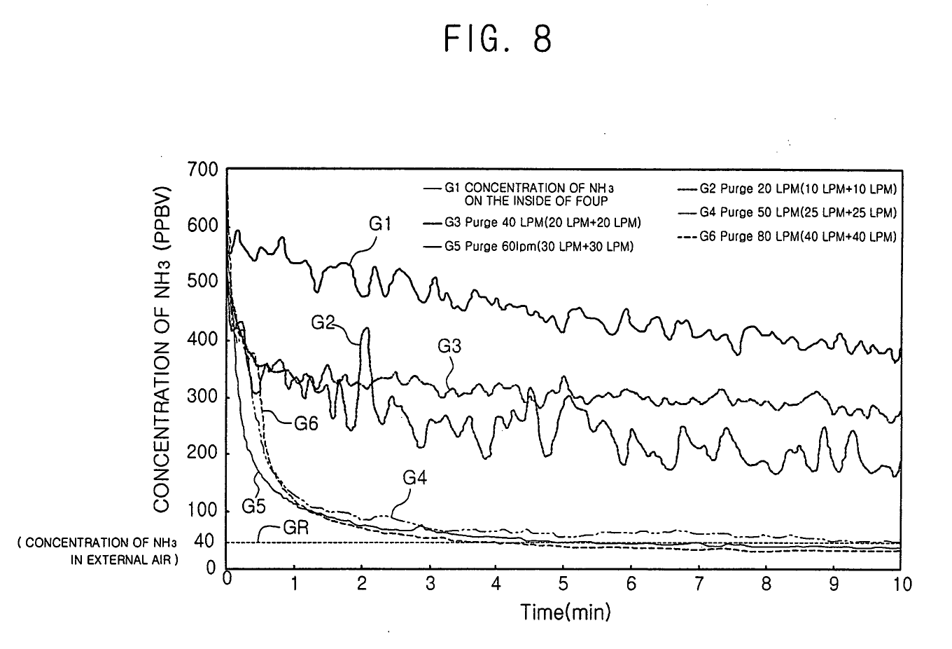

The purging efficiency will be discussed in more detail with reference to FIG. 8. FIG. 8 illustrates graphs representing pollution levels according to the flow rates of the purge gas supplied to an FOUP 10 polluted with NH₃, i.e., an initial pollution level of the FOUP 10 is about 700 ppbv. Each of the graphs of FIG. 8 is obtained by spraying a purge gas from the purge module 60 into the polluted FOUP 10 through the nozzles 62 provided on two opposite sides of the FOUP 10, and measuring a change in the concentration of NH₃ inside the FOUP 10 over time, i.e., purging time. The flow rates and purging time of the purge gas in each graph are varied.

Referring to FIG. 8, a first graph G1 represents a variation in the concentration of NH₃ when the door of the polluted FOUP 10 is left open without using the purge module 60. If the FOUP 10 is purged by natural flow between the EFEM 30 and the FOUP 10, i.e., without use of a purge gas, the concentration of NH₃ gradually and slowly decreases over a long time as shown by the first graph G1. Graphs G2 through G6 represent purging of the FOUP 10 at flow rates of about 20 LPM, 40 LPM, 50 LPM, 60 LPM, and 80 LPM, respectively. In particular, the second graph G2 represents a variation in the concentration of NH₃ when the purge gas is sprayed through the nozzles 62 of the purge module 60 at a total flow rate of about 20 LPM, and the third graph G3 represents a variation in the concentration of NH₃ when the purge gas is sprayed through the nozzles 62 of the purge module 60 at a total flow rate of about 40 LPM. The fourth graph G4 represents a variation in the concentration of NH₃ when the purge gas is sprayed through the nozzles 62 of the purge module 60 at a total flow rate of about 50 LPM, the fifth graph G5 represents a variation in the concentration of NH₃ when the purge gas is sprayed through the nozzles 62 of the purge module 60 at a total flow rate of about 60 LPM, and the sixth graph G6 represents a variation in the concentration of NH₃ when the purge gas is sprayed through the nozzles 62 of the purge module 60 at a total flow rate of about 80 LPM.

As can be seen from the fourth to sixth graphs G4 to G6, if the purge gas is sprayed for about 1 minute to the polluted FOUP 10 at flow rates of about 50 LPM, 60 LPM, and 80 LPM, respectively, the concentration of NH₃ may drop from about 700 ppbv to about 100 ppbv in about 1 minute. Then, the concentration of NH₃ within the FOUP 10 may drop from about 100 ppbv to about 50 ppbv in about additional 2 minutes to 3 minutes. Consequently, if the EFEM 30 and the FOUP 10 are connected to each other and the purge gas is sprayed through the nozzles 62 at a flow rate of about 50 LPM or higher, contaminants or gases released from the wafers 1 of the FOUP 10 may be purged within about 3 minutes, so as to make the concentration of NH₃ in the FOUP 10 substantially equal to a concentration of NH₃ in external air, i.e., illustrated as reference graph GR.

Referring back to operation S30 in FIG. 7, the purge gas may be sprayed to the FOUP 10 through any one of the nozzles 62, as discussed previously with reference to FIGS. 3A-5. For example, if the purge gas is sprayed through a single nozzle 62 at a flow rate of about 50 LPM or higher, contaminants or gases released from the wafers 1 of the FOUP 10 may be purged within about 3 minutes, e.g., make the concentration of NH₃ in the FOUP 10 substantially equal to the concentration of NH₃ in external air shown by a reference graph GR in FIG. 8.

Once purging is done, i.e., purge gas from the FOUP 10 is removed to the EFEM 30, the transfer module 40 may take out one of the wafers 1 from the FOUP 10, and may transfer it to the process module 50 (Operation S40). In this event, the purge gas, i.e., purging operation in operation S30, cleans the wafer 1 to be transferred by the transfer module 40. In other words, in operation S30, the purge module 60 may purge or clean the interior of the FOUP 10 and remove contaminants remaining on the surface of the wafer 1, so the wafer 1 may be clean when transferred by the transfer module 40 to the process nodule 50 in operation S40.

Next, in operation S50, a semiconductor manufacturing process may be performed on the wafer 1 in the process module 50. The semiconductor manufacturing process may include unit processes, e.g., one or more of a deposition process, an etching process, an ion implantation process, a photolithography process, etc. The process module 50 may process the wafers 1, e.g., one by one, in a chamber isolated from the external and under high vacuum conditions, i.e., under pressure lower than normal pressure. Use of high vacuum conditions in the chamber may improve production yield, e.g., prevent or substantially minimize secondary contamination caused by remains of a processing gas on the processed wafer for a long time after process completion.

Next, in operation S60, once the semiconductor manufacturing process of the wafer 1 in the process module 50 is complete, the transfer module 40 may transfer the wafer 1 from the process module 50 back to the FOUP 10. The wafer 1 may be inserted back to the FOUP 10 in reverse order to the order in which the wafers 1 are taken out from the FOUP 10. According to example embodiments, the transfer module 40 may directly transfer the wafer 1 between the process module 50 and the FOUP 10, i.e., without transferring the wafer 1 to separate side storage for purging, so wafer transfer and/or waiting time, i.e., standby time, may be substantially reduced. As such, manufacturing time may be reduced and production yield may be increased.

Next, in operation S70, it may be determined whether all the wafers 1 in the FOUP 10 have undergone the semiconductor manufacturing process in operation S50. If it is determined that all the wafers 1 in the FOUP 10 have been processed in operation S50, the method may proceed to operation S80. Otherwise, the method may return to operation S40. In other words, operations S40 through S70 may be repeated for each wafer 1 in the FOUP 10 until all the wafers 1 in the FOUP 10 are processed. It is noted that earlier processed wafers 1 may have a higher exposure to the purge gas than later processed wafers 1. For this reason, after the last wafer 1 in the FOUP 10 is processed in operation S50 and transferred by the transfer module 40 to the FOUP 10 in operation S60, the purge module 60 may purge the FOUP 10 with all the wafers 1 for a predetermined time period to complete the purging operation that began in operation S30, e.g., purging of the wafers 1 in the FOUP 10 may be continuous or intermittent until operation S80. Therefore, any gases or contaminants remaining on the wafers 1 after the process modules 50 may be removed. For example, when an etching process or a deposition process using a process gas, e.g., NH₃, is performed in the process module 50, any remains of the process gas may be removed form the wafers 1 by the purge module 60 after all the processed wafers 1 are returned to the FOUP 10. As such, secondary contamination of the wafers 1, e.g., product reaction with remains of the process gas on the wafers 1 after processing in the process module 50 is complete, may be prevented or substantially minimized. Once all the wafers 1 are processed and cleaned, i.e., via a final purging of all the processed wafers 1, the purging operation of the purge module 60 is finished (operation S80).

Next, in operation S90, the door 12 of the FOUP 10 may be closed. The module door may be closed together with the door 12. Therefore, the FOUP 10 may be separated, e.g., sealed, from the EFEM 30.

Finally, in operation S100, the FOUP 10 may be unloaded from the load port 20. Then, the FOUP 10 may be transferred by a transport system, e.g., an overhead hoist transport system, for the next process.

The semiconductor manufacturing method according to the exemplary embodiment may include connecting the FOUP 10 with the EFEM 30 to have fluid communication therebetween, and spraying the purge gas onto the surfaces of the wafers of the FOUP 10, i.e., surfaces of wafers already processed or to be processed, connected with the EFEM 30. Since the purge gas is sprayed between all the wafers 1 in the FOUP, there may be sufficient flow between the wafers 1, e.g., as compared to an apparatus having purge gas supplied vertically through a hole at a bottom of the FOUP, thereby improving or maximizing purging efficiency and thus, substantially improving wafer production yield.

Moreover, according to the semiconductor manufacturing method of the exemplary embodiment, as the EFEM 30 may be common to the FOUPs 10 and process modules 50, the purge gas may be directly sprayed into and recovered from the FOUP 10 without a need for separate side storage for the wafers 1. As such, wafers 1 may be transferred directly between the FOUPs 10 and process modules 50, e.g., without a need to transfer wafers to a separate storage for purging purposes, thereby reducing transfer and standby time of wafers. Therefore, productivity of wafer processing may be increased.

In the drawings and specification, there have been disclosed embodiments of the invention and, although specific terms are employed, they are used in a generic and descriptive sense only and not for limitation. While the inventive concepts have been particularly shown and described with reference to exemplary embodiments, it will be understood that various changes in form and details may be made therein without departing from the spirit and scope of the invention, as described by the following claims. Moreover, exemplary embodiments may be applicable to volatile memories, e.g., pseudo SRAMs as well as DRAMs.

What is claimed is:

1. A semiconductor manufacturing apparatus, comprising:
at least one load port configured to receive a front opening unified pod(FOUP) holding a plurality of wafers;
at least one process module configured to perform a semiconductor manufacturing process on the plurality of wafers when the FOUP is loaded on the at least one load port;
an equipment front end module (EFEM) disposed between the at least one load port and the process module, the EFEM having a clean environment therein and being in fluid communication with the FOUP when a door of the FOUP is open;
an opener in the EFEM for opening and closing the door of the FOUP;
a transfer module configured to transfer the plurality of wafers between the FOUP and the process module; and
a purge module configured to spray a purge gas toward the plurality of wafers in the FOUP when the door of the FOUP is open and to remove the purge gas with contaminants from the FOUP to the EFEM.

2. The semiconductor manufacturing apparatus as claimed in claim 1, wherein the purge module includes:
a sensor configured to detect whether the door of the FOUP is open, and
at least one nozzle disposed vertically along at least one side of the FOUP, the nozzle being vertical with respect to surfaces of the plurality of wafers in the FOUP, and the nozzle being configured to spray the purge gas toward the plurality of wafers.

3. The semiconductor manufacturing apparatus as claimed in claim 2, wherein the at least one nozzle includes a plurality of nozzle holes for spraying the purge gas toward the plurality wafers.

4. The semiconductor manufacturing apparatus as claimed in claim 3, wherein the plurality of nozzle holes are arranged vertically along an entire height of the FOUP.

5. The semiconductor manufacturing apparatus as claimed in claim 4, wherein the plurality of nozzle holes are aligned with respective wafers in the FOUP.

6. The semiconductor manufacturing apparatus as claimed in claim 2, wherein the at least one nozzle is on a lateral wall of the EFEM.

7. The semiconductor manufacturing apparatus as claimed in claim 2, wherein the at least one nozzle is on a surface of the EFEM, and a direction of the purge gas from the nozzle is at an angle of about 35 degrees with respect to the surface of the EFEM.

8. The semiconductor manufacturing apparatus as claimed in claim 2, wherein the purge module further comprises:
a gas tank configured to supply the purge gas to the at least one nozzle;
at least one purge gas supply pipeline connecting the gas tank and the at least one nozzle; and
at least one valve configured to control the flow of the purge gas through the at least one purge gas supply pipeline in accordance with whether the door is open.

9. The semiconductor manufacturing apparatus as claimed in claim 1, wherein the purge module is inside the EFEM, the purge module including a plurality of nozzle holes arranged along a height of the FOUP.

10. The semiconductor manufacturing apparatus as claimed in claim 1, wherein the transfer module is configured to transfer the plurality of wafers directly between the FOUP and the process module.

11. A semiconductor manufacturing method, comprising:
loading at least one front opening unified pod (FOUP) holding a plurality of wafers on a load port;
opening a door of the FOUP with an opener to set the FOUP and an equipment front end module (EFEM) in fluid communication with each other, the EFEM having a clean environment and being between the load port and a process module, and the opener being in the EFEM for opening and closing the door of the FOUP;
spraying a purge gas toward the plurality of wafers in the FOUP by a purge module, wherein spraying of the purge gas toward the plurality of wafers in the FOUP continues while the door of the FOUP is open;
transferring the plurality of wafers between the FOUP and the process module by the transfer module;
performing a semiconductor manufacturing process on the plurality of wafers by the process module;
inserting the plurality of wafers into the FOUP; and
removing the purged gas from the FOUP into the EFEM.

12. The semiconductor manufacturing method as claimed in claim 11, wherein transferring the plurality of wafers includes transferring the wafers one-by-one from the FOUP to the process module, while spraying the purge gas into the FOUP.

13. The semiconductor manufacturing method as claimed in claim 11, wherein transferring the plurality of wafers is performed directly between the FOUP and a respective process module.

14. The semiconductor manufacturing method as claimed in claim 11, wherein inserting the plurality of wafers into the FOUP includes positioning processed wafers, after performing a semiconductor manufacturing process, in same respective initial positions in the FOUP.

15. The semiconductor manufacturing method as claimed in claim 11, wherein transferring the plurality of wafers is performed indirectly between the FOUP and a respective process module.
